(19) United States
(12) Patent Application Publication
(10) Pub. No.: US 2021/0222293 A1
(43) Pub. Date: Jul. 22, 2021

(54) Method of Forming Anti-Reflection Coatings

(71) Applicant: IntriEnergy Inc., Naples, FL (US)

(72) Inventor: Franco Gaspari, Toronto (CA)

(21) Appl. No.: 17/151,762

(22) Filed: Jan. 19, 2021

Related U.S. Application Data
(60) Provisional application No. 62/964,331, filed on Jan. 22, 2020.

(51) Int. Cl. C23C 16/27; G02B 1/115; C23C 16/50; C23C 16/52

(52) U.S. Cl. CPC C23C 16/276; C23C 16/52; C23C 16/50; G02B 1/115

(57) ABSTRACT

A method of forming an anti-reflection coating on a substrate uses plasma enhanced vapor deposition techniques including saddle field glow discharge by establishing a first plurality of parameters within a partial vacuum environment, forming a plasma from a gaseous feedstock, and depositing a first layer on the substrate having a first thickness and first index of refraction. While maintaining the vacuum environment, a second plurality of parameters is established by varying at least one of the parameters of the first plurality of parameters, and a second layer is deposited on the first layer having a second thickness and a second index of refraction. Feedstocks include hydrogen, methane and higher order hydrocarbons to form an anti-reflection coating of diamond-like carbon.

### CROSS REFERENCE TO RELATED APPLICATIONS

This application is based upon and claims the benefit of priority to US Provisional Application No. 62/964,331, filed Jan. 22, 2020, and hereby incorporated by reference in its entirety.

### FIELD OF THE INVENTION

This invention relates to methods for forming anti-reflection coatings on surfaces.

### BACKGROUND

An anti-reflection coating comprises one or more optical layers positioned on a substrate to create multiple light reflecting interfaces which generate reflected waves between the interfaces. Using the principle of wave superposition, and with the proper combination of material indices of refraction and layer thicknesses, it is possible to minimize the reflected light (which represents lost energy) and maximize the light transmitted to the substrate by the phenomenon of destructive interference. The choice of refractive indices is crucial for the selection of the range of wavelengths of interest. Anti-reflection coatings can be used at ultra violet wavelengths, as well as in the infrared and visible regions of the electromagnetic spectrum. The visible portion of the spectrum is particularly important for photovoltaic applications. Indeed, an element common to most photovoltaic cells is the presence of an anti-reflection coating to reduce the amount of light reflected at the cell's surface, thus increasing the total energy available for the photovoltaic conversion process. There is clearly an opportunity to improve the efficiency of photovoltaic cell operation by improvements in anti-reflection coatings.

### SUMMARY

The invention concerns a method of forming an anti-reflection coating on a substrate within a control volume. In one example embodiment the method comprises:
creating a partial vacuum within the control volume;
creating a plasma from a mixture of hydrogen gas and a gaseous hydrocarbon within the control volume;
establishing a first plurality of parameters within the control volume, the first plurality of parameters including pressures of the hydrogen gas and the gaseous hydrocarbon, a ratio of the hydrogen gas to the gaseous hydrocarbon, flow rates of the hydrogen gas and the gaseous hydrocarbon into the control volume, a gas mixture rate of the hydrogen gas and the gaseous hydrocarbon or a predetermined gas mixture delivered at a desired flow rate, a temperature of the substrate, a voltage of the substrate, a voltage of an anode within the control volume, an electrical current through the anode, a voltage of a cathode within the control volume;
for a first duration of time using the first plurality of parameters, depositing a first layer comprising diamond-like carbon on the substrate, the first layer having a first thickness and a first index of refraction;
establishing a second plurality of parameters within the control volume by changing at least one of the first plurality of parameters within the control volume while maintaining the partial vacuum within the control volume;
for a second duration of time, depositing a second layer comprising diamond-like carbon on the first layer while maintaining the partial vacuum within the control volume, the second layer having a second thickness and a second index of refraction different from the first index of refraction.

By way of example, the second thickness may be different from the first thickness. In an example method the gaseous hydrocarbon comprises methane and/or higher order hydrocarbons than methane. In an example the first index of refraction ranges from 1.6 to 2.8, and the second index of refraction ranges from 1.6 to 2.8. Further by way of example, the first thickness ranges from 0.1 μm to 0.5 μm and the second thickness ranges from 0.1 μm to 0.5 μm.

In an example embodiment the base vacuum ranges from 1×10⁻⁸ Torr to 5×10⁻⁷ Torr. Further by way of example, partial pressures of the hydrogen gas and the gaseous hydrocarbon range from 50×10⁻³ Torr to 200×10⁻³ Torr.

In an example embodiment the ratio of the hydrogen gas to the gaseous hydrocarbon varies from 0/100 to 20/80 to 40/60 to 50/50 to 60/40 by volume.

In a further example, the flow rates of the hydrogen gas and the gaseous hydrocarbon into the control volume range from 2 sccm to 15 sccm.

In an example embodiment, the gas mixture rate ranges from 2 sccm to 15 sccm. Further by way of example, the temperature of the substrate ranges from 200° C. to 300° C. In an additional example, the voltage of the substrate ranges from 0 volts to 100 volts.

The voltage of an anode within the control volume ranges from 400 volts to 800 volts and the voltage of the cathode ranges from 0 volts to +/−300 volts by way of example. Additionally by way of example, the electrical current through the anode ranges from 20 mA to 300 mA.

In an example anti-reflection coating formed on the substrate according to the invention, the first plurality of parameters comprises:
pressures of the hydrogen gas and the gaseous hydrocarbon of 150×10⁻³ Torr;
the ratio of the hydrogen gas to the gaseous hydrocarbon of 0/100;
the flow rates of the hydrogen gas and the gaseous hydrocarbon into the control volume of 5 sccm;
the temperature of the substrate of 200° C.;
the voltage of the substrate of 0 volts;
the voltage of the anode within the control volume of 650+/−50 volts;
the voltage of the cathode within the control volume of 0 volts;
the electrical current through the anode of 20+/−2 mA.

In forming this example anti-reflection coating the first layer comprising diamond-like carbon is deposited for the first duration of time of 10 minutes on the substrate. The first layer has a first thickness of approximately 0.2 μm and a first index of refraction of 1.6. The second plurality of parameters is established by changing the voltage of the substrate to 300 volts, and the second layer comprising diamond-like carbon is deposited for the second duration of time of 10 minutes on the first layer. The second layer has a second thickness of approximately 0.1 μm and a second index of refraction of 1.9.

In a further example, a method of forming an anti-reflection coating on a substrate within a control volume may comprise:
creating a partial vacuum within the control volume;
creating a plasma from a gaseous feedstock within the control volume;
establishing a first plurality of parameters within the control volume, the first plurality of parameters including pressures of the gaseous feedstock, a ratio of constituents of the gaseous feed stock, flow rates of the constituents into the control volume, a gas mixture rate of the constituents (or a predetermined gas mixture delivered at a desired flow rate), a temperature of the substrate, a voltage of the substrate, a voltage of an anode within the control volume, an electrical current through the anode, a voltage of a cathode within the control volume;
for a first duration of time using the first plurality of parameters, depositing a first layer on the substrate, the first layer having a first thickness and a first index of refraction;
establishing a second plurality of parameters within the control volume by changing at least one of the first plurality of parameters within the control volume while maintaining the partial vacuum within the control volume;
for a second duration of time, depositing a second layer on the first layer while maintaining the partial vacuum within the control volume, the second layer having a second thickness and a second index of refraction different from the first index of refraction.

### BRIEF DESCRIPTION OF THE DRAWINGS

FIG. 1 is a flow chart illustrating an example method of forming an anti-reflection coating on a substrate according to the invention;

FIG. 2 is a schematic diagram of an apparatus used to form an anti-reflection coating according to the method illustrated in FIG. 1; and

FIG. 3 is a schematic representation of an anti-reflection coating on a substrate.

### DETAILED DESCRIPTION

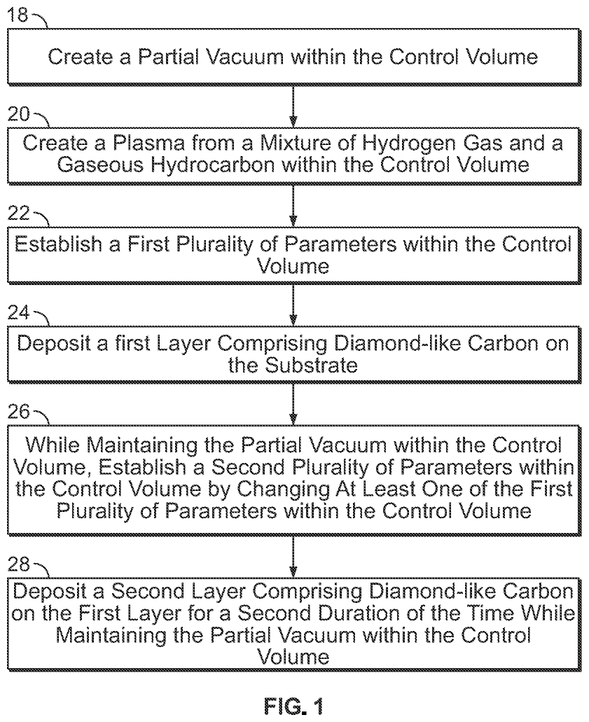

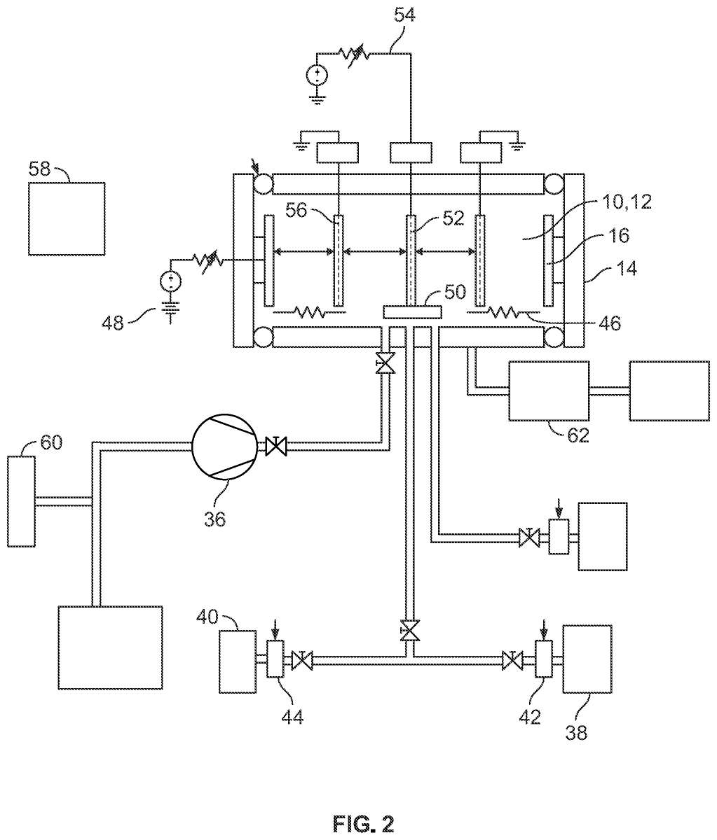

An example method of forming an anti-reflection coating on a substrate is illustrated in the flow diagram of FIG. 1. The example method according to the invention is advantageously accomplished using saddle field glow discharge (SFGD) techniques, a type of plasma enhanced vapor deposition (PECVD). PECVD techniques are well established and not described in detail in this specification. The method is executed within a control volume 10 defined by the vacuum chamber 12 of a PECVD device 14 which contains one or more substrates 16, an example of which is illustrated schematically in FIG. 2. By way of example, the substrates may be photovoltaic cells, optical lenses, mirrors, optical filters and the like.

The example method according to the invention uses hydrogen and gaseous hydrocarbon compounds such as methane and/or higher order hydrocarbons (precursor gases) to form the anti-reflection coating of diamond-like carbon. The example method illustrated in FIG. 1 comprises:
creating a partial vacuum within the control volume (18);
creating a plasma from a precursor gas mixture of hydrogen gas and a gaseous hydrocarbon within the control volume (20); and
establishing a first plurality of parameters within the control volume (22). The first plurality of parameters are the conditions within the control volume 10 of the PECVD device 14 which will result in the formation of the anti-reflection coating on the substrate 16. The parameters include:

1. pressures of the hydrogen gas and the gaseous hydrocarbon;

2. a ratio of the hydrogen gas to the gaseous hydrocarbon;

3. flow rates of the hydrogen gas and the gaseous hydrocarbon into the control volume;

4. a gas mixture rate of the hydrogen gas and the gaseous hydrocarbon or a predetermined gas mixture delivered at a desired flow rate;

5. a temperature of the substrate;

6. a voltage of the substrate;

7. a voltage of an anode and a cathode within the control volume;

8. an electrical current through the anode.

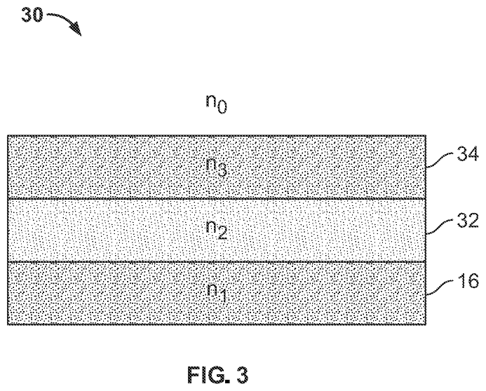

The first plurality of parameters are used to deposit a first layer comprising diamond-like carbon on the substrate (24). The first layer has a first thickness and a first index of refraction which are tuned to one or more particular optical wavelengths of interest based upon the purpose of the substrate. For a photovoltaic cell operating in ambient air for example (see FIG. 3), light in the visible spectrum is of interest and the first layer thickness and index of refraction are determined by the relations t=λ/4n₁ and n₂=sqrt(n₀×n₁) where t=layer thickness, λ=wavelength of interest, n₁ is the index of refraction of the substrate (typically 3.8 for crystalline silicon photovoltaic cells), n₂ is the index of refraction of the first layer and n₀ is the index of refraction of ambient air.

Once the first anti-reflection layer is formed a second plurality of parameters is established within the control volume by changing at least one of the first plurality of parameters within the control volume (26). This is accomplished while maintaining the partial vacuum within the control volume. Upon establishment of the second plurality of parameters a second layer comprising diamond-like carbon is deposited on the first layer for a second duration of time while maintaining the partial vacuum within the control volume (28). The second layer has a second thickness (which may or may not be different from the thickness of the first layer) and a second index of refraction different from the first index of refraction.

By way of a practical example the parameters of the example method may have the following values:

1. both the first and second indices of refraction may range from 1.6 to 2.8;

2, the first and second thicknesses may range from 0.1 μm to 0.5 μm;

3. the base vacuum before introducing the precursor gas mixture may range from 1×10⁻⁸ Torr to 5×10⁻⁷ Torr;

4. the partial vacuum within the control volume with the precursor gas mixture may range from 10×10⁻³ Torr to 300×10⁻³ Torr

5. the ratio of the hydrogen gas to the gaseous hydrocarbon may vary from 0/100 to 20/80 to 40/60 to 50/50 to 60/40 by volume;

6. the flow rates of the hydrogen gas and the gaseous hydrocarbon into the control volume may range from 2 sccm to 15 sccm;

7. the gas mixture rate may range from 2 sccm to 15 sccm;

8. the temperature of the substrate may range from 200° C. to 300° C.;

9. the voltage of the substrate may range from 0 volts to 100 volts;

10. the voltage of the anode within the control volume may range from 400 volts to 800 volts;

11. the electrical current through the anode may range from 30 mA to 50 mA; and

12. the electrical current of the substrate may range from 0 mA to +/−10 mA.

FIG. 3 illustrates an experimental anti-reflection coating 30 formed on the substrate 16 using the example method according to the invention. Substrate 16 comprises a silicon wafer having an index of refraction of 3.8 and the anti-reflection coating 30 comprises first and second respective layers 32 and 34. First layer 32 has an index of refraction of 1.6 and a thickness of approximately 0.1 μm; the second layer 34 has an index of refraction of 1.9 and a thickness of on the order of approximately 0.1 μm. Both layers are tuned to operate over a range of wavelengths from 200 nm to 600 nm which encompasses a portion of the visible spectrum. The anti-reflection coating 30 was formed on the substrate 16 using SFGD techniques using a PECVD device similar to the device 14 shown schematically in FIG. 2.

The example method to form the anti-reflection coating 30 was pursued by first using a pump 36 to create a base vacuum of 1×10⁻⁷ Torr within the vacuum chamber 12 comprising the control volume 10. Next, the first plurality of parameters were established within the control volume 10. Hydrogen gas and gaseous hydrocarbon (methane in this example) were fed into the control volume 10 from respective reservoirs 38 and 40 using respective mass flow controllers 42 and 44 to set the ratio of the hydrogen gas to the gaseous hydrocarbon of 20/80, the flow rates of the gas mixture of the hydrogen gas and the gaseous hydrocarbon of 5 sccm. (Alternately, the precursor gases could be mixed according to the desired ratio in a mixing bottle and the gas mixture input at a particular flow rate.) The temperature of the substrate 16 of 250° C. was established and maintained using thermal conditioning elements 46 (for example, electrical resistance heaters) and the substrate was maintained at a voltage of 0 volts using a voltage source 48. The gases within the control volume 10 were formed into a plasma using a DC power supply SL600 (54) and the voltage of the anode 52 within the control volume was set to 560 volts +/−20 volts, with a corresponding electrical current through the anode 50 of 200 mA+/−2 mA being maintained. Cathode 56 within the control volume 10 was grounded at 0 volts. The plasma ions were accelerated toward the substrate 16 and by the voltage difference between the anode 50 and cathode 54 and the first layer 32 comprising diamond-like carbon was deposited on the substrate for the first duration of time of 5 minutes resulting in the first layer having a first thickness of approximately 0.1 μm and a first index of refraction of 1.6. Control of device 14 is accomplished via a microprocessor 58 executing resident control algorithms in response to feedback from temperature and pressure sensors 60 and 62 as is understood for PECVD devices.

While maintaining vacuum conditions within the control volume 10 the second plurality of parameters were established by changing the voltage of the substrate 16 to 300 volts. The second layer 34 comprising diamond-like carbon was deposited on the on the first layer 32 for the second duration of time of 5 minutes. This resulted in the second layer having a second thickness of approximately 0.1 μm and a second index of refraction of 1.9. Reflectivity measurements conducted on the experimental substrate 16 having the anti-reflection coating 30 showed a percent reflectivity below 0.1% for wavelengths from 200 nm to 350 nm and a percent reflectivity below 0.25% for wavelengths from 350 nm to 600 nm.

What is claimed is:

1. A method of forming an anti-reflection coating on a substrate within a control volume, said method comprising:
creating a partial vacuum within said control volume;
creating a plasma from a mixture of hydrogen gas and a gaseous hydrocarbon within said control volume;
establishing a first plurality of parameters within said control volume, said first plurality of parameters including pressures of said hydrogen gas and said gaseous hydrocarbon, a ratio of said hydrogen gas to said gaseous hydrocarbon, flow rates of said hydrogen gas and said gaseous hydrocarbon into said control volume, a gas mixture rate of said hydrogen gas and said gaseous hydrocarbon or a predetermined gas mixture delivered at a desired flow rate, a temperature of said substrate, a voltage of said substrate, a voltage of an anode within said control volume, an electrical current through said anode, a voltage of a cathode within said control volume;
for a first duration of time using said first plurality of parameters, depositing a first layer comprising diamond-like carbon on said substrate, said first layer having a first thickness and a first index of refraction;
establishing a second plurality of parameters within said control volume by changing at least one of said first plurality of parameters within said control volume while maintaining said partial vacuum within said control volume;
for a second duration of time, depositing a second layer comprising diamond-like carbon on said first layer while maintaining said partial vacuum within said control volume, said second layer having a second thickness and a second index of refraction different from said first index of refraction.

2. The method according to claim 1, wherein said second thickness is different from said first thickness.

3. The method according to claim 1, wherein said gaseous hydrocarbon comprises methane.

4. The method according to claim 1, wherein said gaseous hydrocarbon comprises a hydrocarbon of higher order than methane.

5. The method according to claim 1, wherein said first index of refraction ranges from 1.6 to 2.8.

6. The method according to claim 1, wherein said second index of refraction ranges from 1.6 to 2.8.

7. The method according to claim 1, wherein said first thickness ranges from 0.1 μm to 0.5 μm.

8. The method according to claim 1, wherein said second thickness ranges from 0.1 μm to 0.5 μm.

9. The method according to claim 1, wherein said base vacuum ranges from 1×10⁻⁸ Torr to 5×10⁻⁷ Torr.

10. The method according to claim 1, wherein partial pressures of said hydrogen gas and said gaseous hydrocarbon range from 50×10⁻³ Torr to 200×10⁻³ Torr.

11. The method according to claim 1, wherein said ratio of said hydrogen gas to said gaseous hydrocarbon varies from 0/100 to 20/80 to 40/60 to 50/50 to 60/40 by volume.

12. The method according to claim 1, wherein said flow rates of said hydrogen gas and said gaseous hydrocarbon into said control volume range from 2 sccm to 15 sccm.

13. The method according to claim 1, wherein said gas mixture rate ranges from 2 sccm to 15 sccm.

14. The method according to claim 1, wherein said temperature of said substrate ranges from 200° C. to 300° C.

15. The method according to claim 1, wherein said voltage of said substrate ranges from 0 volts to 100 volts.

16. The method according to claim 1, wherein said voltage of an anode within said control volume ranges from 400 volts to 800 volts and said voltage of said cathode ranges from 0 volts to +/−300 volts.

17. The method according to claim 1, wherein said electrical current through said anode ranges from 20 mA to 300 mA.

18. An anti-reflection coating formed on said substrate according to the method of claim 1, wherein said first plurality of parameters comprises:
said pressures of said hydrogen gas and said gaseous hydrocarbon of 150×10⁻³ Torr;
said ratio of said hydrogen gas to said gaseous hydrocarbon of 0/100;
said flow rates of said hydrogen gas and said gaseous hydrocarbon into said control volume of 5 sccm;
said temperature of said substrate of 200° C.;
said voltage of said substrate of 0 volts;
said voltage of said anode within said control volume of 650+/−50 volts;
said voltage of said cathode within said control volume of 0 volts;
said electrical current through said anode of 20+/−2 mA;
said first layer comprising diamond-like carbon being deposited for said first duration of time of 10 minutes on said substrate, said first layer having a first thickness of approximately 0.2 μm and a first index of refraction of 1.6;
said second plurality of parameters being established by changing said voltage of said substrate to 300 volts; and
said second layer comprising diamond-like carbon being deposited for said second duration of time of 10 minutes on said first layer, said second layer having a second thickness of approximately 0.1 μm and a second index of refraction of 1.9.

19. A method of forming an anti-reflection coating on a substrate within a control volume, said method comprising:
creating a partial vacuum within said control volume;
creating a plasma from a gaseous feedstock within said control volume;
establishing a first plurality of parameters within said control volume, said first plurality of parameters including pressures of said gaseous feedstock, a ratio of constituents of said gaseous feed stock, flow rates of said constituents into said control volume, a gas mixture rate of said constituents or a predetermined gas mixture delivered at a desired flow rate, a temperature of said substrate, a voltage of said substrate, a voltage of an anode within said control volume, an electrical current through said anode, a voltage of a cathode within said control volume;
for a first duration of time using said first plurality of parameters, depositing a first layer on said substrate, said first layer having a first thickness and a first index of refraction;
establishing a second plurality of parameters within said control volume by changing at least one of said first plurality of parameters within said control volume while maintaining said partial vacuum within said control volume;
for a second duration of time, depositing a second layer on said first layer while maintaining said partial vacuum within said control volume, said second layer having a second thickness and a second index of refraction different from said first index of refraction.
